(19) United States
(12) Patent Application Publication
(10) Pub. No.: US 2005/0287793 A1
(43) Pub. Date: Dec. 29, 2005

(54) Diffusion barrier process for routing polysilicon contacts to a metallization layer

(75) Inventors: Aaron R. Blanchet, Boise, ID (US); Roger W. Lindsay, Boise, ID (US); Robert C. Carr, Boise, ID (US)

Correspondence Address: LEFFERT JAY & POLGLAZE, P.A., P.O. BOX 581009, MINNEAPOLIS, MN, 55458-1009, US

(73) Assignee: Micron Technology, Inc.

(21) Appl. No.: 10/881,303

(22) Filed: Jun. 29, 2004

(51) Int. Cl. H01L 21/336; H01L 29/40

(52) U.S. Cl. 438/629; 257/774; 257/773; 257/775; 257/776; 438/638; 438/619

(57) ABSTRACT

Methods and apparatus are described to facilitate forming of polysilicon contact plugs with an improved diffusion barrier that can be formed in conjunction with other process steps. Embodiments of the present invention are formed by recessing the polysilicon plug below the surface of the insulation layer, allowing the depression formed at the interface of the insulating layer and the top of the polysilicon plug to be filled with a diffusion barrier/liner layer before deposition and etching of the metal interconnection layer. This allows the etching of the polysilicon contact plug and deposition of the barrier layer to occur along with other process steps. In an embodiment of the present invention the peripheral metal contact plugs and polysilicon contact plugs of a memory array are deposited with liner material and removed in a series of concurrent process steps.

### TECHNICAL FIELD OF THE INVENTION

The present invention relates generally to integrated circuit devices and, in particular, to the formation of diffusion barriers for routing polysilicon contacts to a metallization layer for integrated circuits or semiconductor memory devices.

### BACKGROUND OF THE INVENTION

Memory devices are typically provided as internal storage areas in the computer. The term memory identifies data storage that comes in the form of integrated circuit chips. In general, memory devices contain an array of memory cells for storing data, and row and column decoder circuits coupled to the array of memory cells for accessing the array of memory cells in response to an external address.

There are several different types of memory used in modern electronics, one common type is RAM (random-access memory). RAM is characteristically found in use as main memory in a computer environment. RAM refers to read and write memory; that is, you can both write data into RAM and read data from RAM. This is in contrast to read-only memory (ROM), which permits you only to read data. Most RAM is volatile, which means that it requires a steady flow of electricity to maintain its contents. As soon as the power is turned off, whatever data was in RAM is lost.

One other type of non-volatile memory is known as Flash memory. A flash memory is a type of EEPROM (electrically-erasable programmable read-only memory) that can be erased and reprogrammed in blocks. A typical flash memory comprises a memory array that includes a large number of memory cells arranged in row and column fashion. Each of the memory cells includes a floating-gate field-effect transistor capable of holding a charge. The cells are usually grouped into blocks. Each of the cells within a block can be electrically programmed in a random basis by charging the floating gate. The charge can be removed from the floating gate by a block erase operation. The data in a cell is determined by the presence or absence of the charge in the floating gate.

Flash memory typically utilizes one of two basic architectures known as NOR flash and NAND flash. The designation is derived from the logic used to read the devices. In NOR flash architecture, a column of memory cells are coupled in parallel with each memory cell coupled to a bit line. In NAND flash architecture, a column of memory cells are coupled in series with only the first memory cell of the column coupled to a bit line.

Integrated circuit fabricators are continuously seeking to reduce the size of the devices. Smaller devices facilitate higher productivity and reduced power consumption. However, as device sizes become smaller, the sizes of various standard features become increasingly important. This is true in particular for semiconductor memory arrays where a small decrease in size of a feature can be magnified by being repeated throughout the array. One such repeated feature in memory arrays are the interconnect lines that form the source supply lines, bit lines, and word lines of the memory array. These interconnect lines are typically placed on an insulating layer formed over the active regions of the memory array. They couple to the active regions of the memory by way of contact plugs placed in vias formed in the insulating layer that contact the local source, drains, and/or control gates of memory cells and other circuits of the memory array. In addition, as feature size is reduced, the resistance of interconnect lines, and in particular, polysilicon interconnect lines, increases. This makes the use of lower resistance metal interconnect lines increasingly important close to the active silicon device that is producing or receiving the signal the line is designed to carry. Three commonly utilized metals for interconnect lines of a “metal layer,” as the metal based interconnect layer of the integrated circuit is commonly referred to, are aluminum, copper, and tungsten.

A common problem in making these connections to a metal interconnect line is forming the contact plugs to contact to the active silicon area through the layer of insulator. Two common techniques utilize either metal (such as tungsten or titanium) or polysilicon plugs to form these contacts. Due to the isolation and manufacturing techniques required, metal plugs tend to have larger features, but be of lower resistance, than polysilicon contact plugs. In addition, the chemistry of polysilicon plugs can be tuned to have a lower leakage current than metal plugs, but typically at the expense of a higher resistance. Thus, where feature size and leakage are a consideration, metal contact plugs tend to be mainly used for high speed connections and polysilicon plugs utilized where size and lower leakage are of importance (such as within the body of a memory array).

The contact plugs are typically formed by masking and etching contact via holes down to the active silicon area to be contacted to through an insulation layer that has been laid down over the active silicon layer. The metal or polysilicon is then deposited and polished and/or etched back to fill the holes to form contact plugs, followed by a metal layer. The metal layer is deposited, masked, and etched on the insulation layer to form a series of interconnect lines and connect to the metal or polysilicon contact plugs.

A problem with silicon materials of integrated circuits, such as polysilicon contact plugs, is that they cannot typically be in direct contact or directly connected to the metal of the interconnect lines, in particular, with aluminum interconnect lines, because of diffusion or migration of the metal into the surrounding silicon materials or the polysilicon of a polysilicon contact plug. This diffusion is particularly an issue with any later high temperature processing and can cause defects and failures in the resulting integrated circuit. The interconnect processes and/or metal layers therefore typically employ “liner” materials that are deposited on top of the integrated circuit or silicon materials to act as a diffusion barrier and, at the same time, provide a good electrical connection between the contact plug and the metal of the interconnection line. In some cases a second layer of liner material is also deposited on top of the metal of the interconnect process/metal layer after it has been deposited to further protect from diffusion into any further silicon material layers or contact plugs placed over the interconnect process/metal layer. These liner materials are often thinly deposited and thus the barrier is at a higher risk of having metal diffusion occur through it. To deal with a thin liner material/diffusion barrier layer, which is desirable because of its lower resistance, in many cases a more stable/less diffusion prone metal, such as tungsten, is used in the interconnect. Alternately, a local interconnect of polysilicon is used, in particular, where polysilicon contact plug is to be connected to. However these less diffusion prone metals and/or polysilicon local interconnect lines also have an increased resistance and therefore a reduced performance. This reduces the overall circuit performance and increases the likelihood of the designer adding more circuit layers and process steps in the design to compensate, which, in turn, can increase the manufacturing costs and complexity of the resulting integrated circuit.

For the reasons stated above, and for other reasons stated below which will become apparent to those skilled in the art upon reading and understanding the present specification, there is a need in the art for alternate methods and apparatus for coupling polysilicon contact plugs to metal interconnect lines.

### SUMMARY OF THE INVENTION

The above-mentioned problems with polysilicon contact plugs and other problems are addressed by the present invention and will be understood by reading and studying the following specification.

Various embodiments of the invention facilitate forming of polysilicon contact plugs with a diffusion barrier with increased thickness that can be formed in conjunction with other steps and thus requires no additional processing. Embodiments of the present invention are formed by recessing the polysilicon plug below the surface of the insulation layer (the interlayer dielectric (ILD) or interlayer isolation stack), allowing the depression formed at the interface of the insulating layer and the top of the polysilicon plug to be filled with a diffusion barrier/liner layer. This also allows the etching of the polysilicon contact plug and deposition of the barrier layer to occur concurrent with formation of metal contact plugs and before deposition and etching of the metal interconnection layer. In one embodiment of the present invention, both metal contact plugs and polysilicon contact plugs are deposited with liner material in a single process step. In another embodiment of the present invention the peripheral tungsten metal contact plugs are formed and the polysilicon contact plugs of a memory array are deposited with liner material and etched in a series of concurrent process steps and a layer of aluminum is deposited and etched to form metal interconnect lines in contact with the peripheral tungsten metal and polysilicon contact plugs.

For one embodiment, the invention provides a portion of an integrated circuit comprising a polysilicon contact plug in contact with a first active area of the integrated circuit and a liner material overlying the polysilicon plug, and a metal contact in contact with a second active area of the integrated circuit, and wherein the metal contact and the liner material of the polysilicon contact plug are formed concurrently.

For another embodiment, the invention provides a method of forming a portion of an integrated circuit comprising forming a dielectric layer overlying a silicon active area of the integrated circuit, forming a first contact hole in the dielectric layer exposing a first portion of the silicon active area, forming a polysilicon layer overlying the dielectric layer and contacting the first portion of the silicon active area, removing a portion of the polysilicon layer to leave a polysilicon plug in the first contact hole, wherein a surface of the polysilicon plug is recessed below a surface of the dielectric layer, forming a second contact hole in the dielectric layer exposing a second portion of the silicon active area, forming a conductive layer overlying the dielectric layer and contacting the surface of the polysilicon plug and the second portion of the silicon active area, and removing a portion of the conductive layer to leave portions of the conductive layer in the second contact hole and in the first contact hole between the surface of the dielectric layer and the surface of the polysilicon plug.

For yet another embodiment, the invention provides a method of forming polysilicon and metal contact plugs comprising forming an insulation layer overlying an active area of an integrated circuit, forming one or more first and second contact holes in the insulation layer, forming a polysilicon layer over the insulation layer in contact with the active area through the one or more first contact holes, removing a portion of the polysilicon layer to form one or more polysilicon contact plugs in the one or more contact holes, wherein a top surface of each of the one or more polysilicon contact plugs are formed below a top surface of the insulation layer, forming a contact liner material layer over the insulation layer in contact with the top surface of each of the one or more polysilicon contact plugs and second contact holes, and removing a portion of the contact liner material layer to form a diffusion barrier over each polysilicon contact plug in the one or more contact holes and one or more metal contact plugs in the one or more second contact holes.

For a further embodiment, the invention provides a memory array comprising an array of memory cells, an interlayer dielectric (ILD) isolation layer placed over the array, wherein the ILD isolation layer has one or more first and second contact holes, one or more polysilicon contact plugs wherein the polysilicon contact plugs are formed within the one or more first contact holes of the ILD isolation layer, where a top surface of each of the one or more polysilicon contact plugs is positioned below a top surface of the ILD isolation layer, defining one or more depressions, one or more barrier layers of contact liner material placed in each of the one or more depressions, one or more metal contact plugs, wherein the metal contact plugs are formed in the one or more second contact holes, and at least one metal interconnect line in contact with the one or more barrier layers and/or metal contact plugs.

For a yet further embodiment, the invention provides a system comprising a processor coupled to a memory device. The memory device comprises an array of memory cells, an interlayer dielectric (ILD) isolation layer placed over the array, wherein the ILD isolation layer has one or more first and second contact holes, one or more polysilicon contact plugs placed within the one or more first contact holes of the ILD isolation layer, wherein a top surface of each of the one or more polysilicon contact plugs is positioned below a top surface of the ILD isolation layer, defining one or more depressions, one or more barrier layers of contact liner material, wherein the barrier layers are formed in each of the one or more depressions, one or more metal contact plugs, wherein the metal contact plugs are formed of contact liner material in the one or more second contact holes concurrently with the one or more barrier layers, and at least one metal interconnect line in contact with the one or more barrier layers and/or metal contact plugs.

For another embodiment, the invention provides a method of forming polysilicon contact plugs comprising forming an insulation layer overlying an active area of an integrated circuit, forming one or more contact holes in the insulation layer, forming a polysilicon layer over the insulation layer in contact with the active area through the one or more contact holes, removing a portion of the polysilicon layer to form one or more polysilicon contact plugs in the one or more contact holes, wherein a top surface of each of the one or more polysilicon contact plugs are formed below a top surface of the insulation layer, and forming a contact liner material layer over the insulation layer in contact with the top surface of each of the one or more polysilicon contact plugs to form a diffusion barrier over each polysilicon contact plug in the one or more contact holes.

The invention further provides methods and apparatus of varying scope.

### BRIEF DESCRIPTION OF THE DRAWINGS

FIG. 1 details a cross-sectional view of a portion of an integrated circuit or a memory array of the prior art showing metal and polysilicon contact plugs.

FIGS. 2A-2F are cross-sectional views of a portion of an integrated circuit or a memory array during various stages of fabrication in accordance with an embodiment of the invention.

FIG. 3 is a functional block diagram of a basic flash memory device in accordance with an embodiment of the invention coupled to a processor.

### DETAILED DESCRIPTION OF THE INVENTION

In the following detailed description of the preferred embodiments, reference is made to the accompanying drawings that form a part hereof, and in which is shown by way of illustration specific embodiments in which the inventions may be practiced. These embodiments are described in sufficient detail to enable those skilled in the art to practice the invention, and it is to be understood that other embodiments may be utilized and that process or mechanical changes may be made without departing from the scope of the present invention. The terms wafer and substrate used previously and in the following description include any base semiconductor structure. Both are to be understood as including silicon-on-sapphire (SOS) technology, silicon-on-insulator (SOI) technology, thin film transistor (TFF) technology, doped and undoped semiconductors, epitaxial layers of silicon supported by a base semiconductor, as well as other semiconductor structures well known to one skilled in the art. Furthermore, when reference is made to a wafer or substrate in the following description, previous process steps may have been utilized to form regions/junctions in the base semiconductor structure. The following detailed description is, therefore, not to be taken in a limiting sense, and the scope of the present invention is defined only by the appended claims and their equivalents.

Embodiments of the invention facilitate forming of polysilicon contact plugs with a diffusion barrier with increased thickness that can be formed in conjunction with other steps and thus requires no additional processing. Embodiments of the present invention are formed by recessing the polysilicon plug below the surface of the insulation layer, allowing the depression formed at the interface of the insulating layer and the top of the polysilicon plug to be filled with a diffusion barrier/liner layer. This also allows the etching of the polysilicon contact plug and deposition of the barrier layer to occur concurrent with formation of metal contact plugs and before deposition and etching of the metal interconnection layer. In one embodiment of the present invention, both metal contact plugs and polysilicon contact plugs are deposited with liner material in a single process step. In one embodiment of the present invention, both metal contact plugs and polysilicon contact plugs are deposited with liner material in a single process step. In another embodiment of the present invention the peripheral tungsten metal contact plugs are formed and the polysilicon contact plugs of a memory array are deposited with liner material and removed in a series of concurrent process steps and a layer of aluminum is deposited and removed to form metal interconnect lines in contact with the peripheral tungsten metal and polysilicon contact plugs.

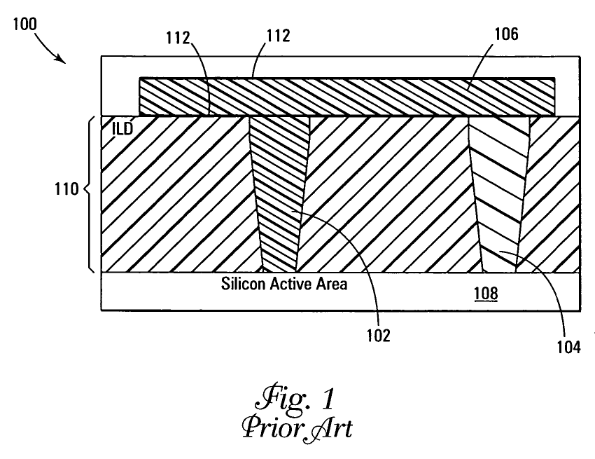

FIG. 1 depicts a section of an integrated circuit 100 of the prior art that utilizes a polysilicon contact plug 102 and/or a peripheral metal contact plug 104 to couple to a tungsten metal or polysilicon interconnect line 106. In FIG. 1, an interlayer dielectric (ILD) stack 110, which can be of one or more appropriate insulator materials, such as, but not limited to silicon oxide, borophosphosilicate glass (BPSG), and tetraethylorthosilicate (TEOS), is formed over an active silicon area 108 containing transistors and other active elements of the integrated circuit, for example a floating gate memory array of a Flash memory. A polysilicon contact plug 102 is formed in one contact hole to contact to the silicon active area 108, and a tungsten metal contact plug 104 is formed in another contact hole.

On the polysilicon contact plug 102, a barrier/liner layer 112 of tungsten, titanium, or titanium nitride is formed over the top of the polysilicon contact plug 102. As noted above, this barrier layer 112 is formed thin and in many cases can require additional process steps to form. An interconnect line of tungsten or polysilicon 106 is then formed over the ILD insulator stack 110 and couples to the peripheral tungsten contact plugs 104 and to the polysilicon contact plugs 106 through the barrier layer 112. A second of barrier/liner layer 112 is in many cases deposited over the interconnect line to protect subsequent process layers from diffusion. As also noted above, this thin barrier/liner layer 112 can often be diffused through, in particular during later high temperature processing such as annealing, and, in addition, is more subject to faults due to it relative thinness and lack of edge coverage.

As stated above, embodiments of the present invention are formed by recessing the polysilicon plugs of the integrated circuit or memory device below the surface of the insulation layer. The resulting depression formed at the interface of the insulating layer and the top of each polysilicon plug is filled with a diffusion barrier/liner material before deposition and etching of the metal interconnection layer. This allows the formation of a thick diffusion barrier while also allowing for the etching and deposition of the barrier layer/liner material of the polysilicon contact plugs and metal contact plugs to occur within concurrent process steps.

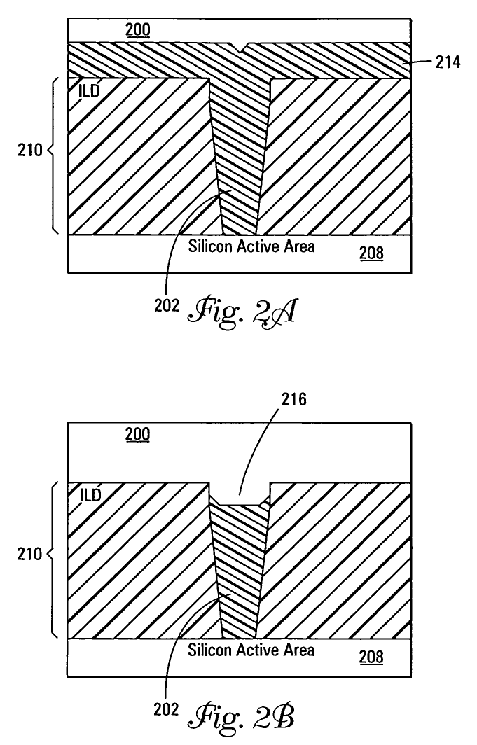

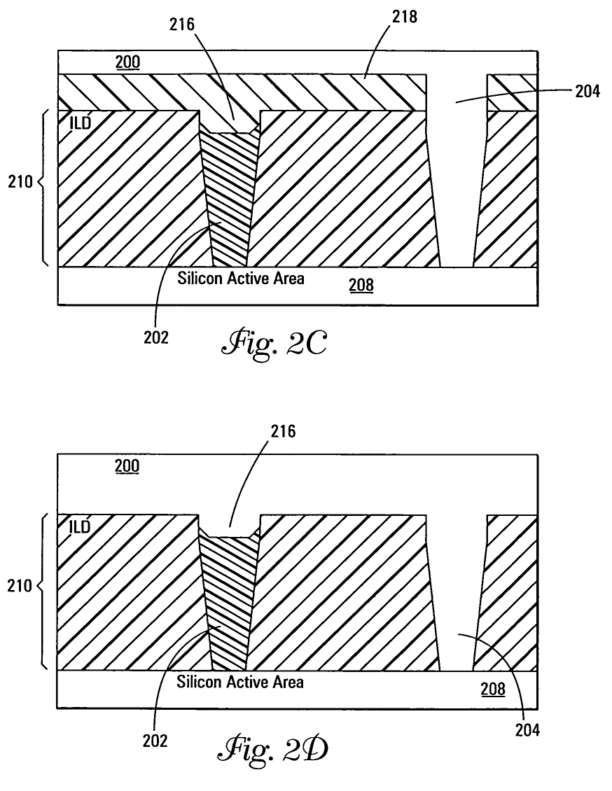

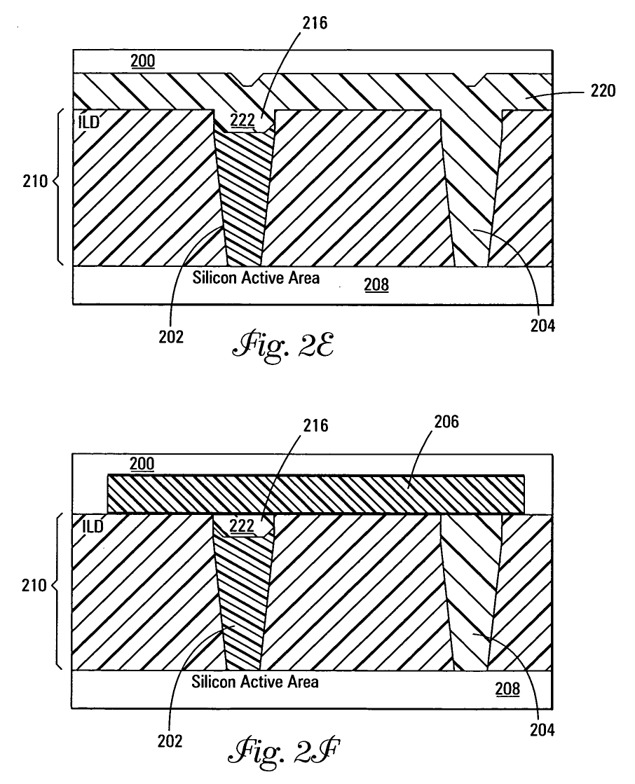

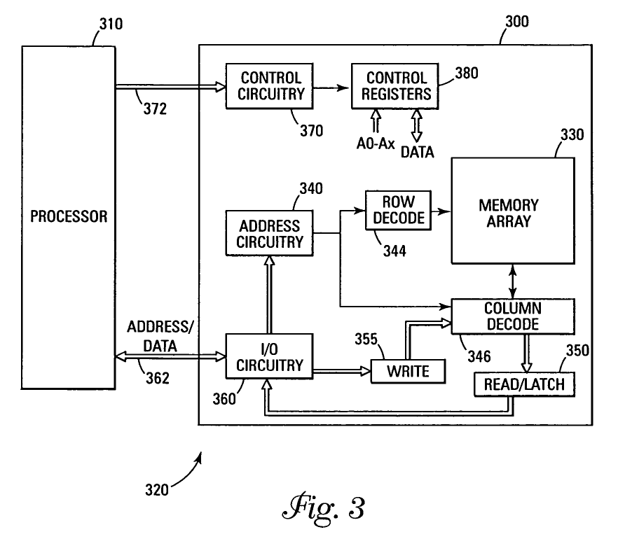

FIGS. 2A-2F generally depict a method of forming a portion of a memory array in accordance with an embodiment of the invention. FIG. 2A depicts a portion of the memory array after several processing steps have occurred. Formation of the structure depicted in FIG. 2A is well known and will not be detailed herein. In general, FIG. 2A depicts a cross section of a silicon active area and ILD insulator stack that will form a portion of the memory array. It is noted that as embodiments of the present invention generally are formed or utilized after the active silicon area and ILD insulator stack has been formed, they therefore are not limited to a particular silicon active area or ILD insulator stack configuration of an integrated circuit and that the memory array shown in FIG. 2A is but one possible embodiment of the present invention. It is noted that the formation of the memory array of FIGS. 2A-2F is for illustrative purposes and that embodiments of the present invention are broadly applicable to integrated circuits in general.

In FIG. 2A, a side view of a portion of a partially formed memory array, such as of a flash memory array, is detailed. A silicon active area 208 containing transistors and other active elements of a floating gate memory array (not shown in FIG. 2A) is shown with an interlayer dielectric (ILD) isolation stack 210 formed over it. The ILD isolation stack 210 can contain one or more insulation layers. This ILD isolation stack 210, as detailed above in reference to FIG. 1, can also be formed of one or more other appropriate insulator materials. A contact hole 202 to form a contact plug has been formed in the ILD isolation stack 210 to the silicon active area 208 and layer of polysilicon deposited over the top of the ILD isolation stack 210 filling the contact hole 202 with polysilicon.

This layer of polysilion 214 is then removed or etched such that it removes the excess polysilicon and leaves the polysilicon contact plug formed in the contact hole 202. As shown in FIG. 2B, the polysilicon is slightly over-etched to etch the polysilicon contact plug 202 below the top surface of the ILD isolation stack 210. This over-etching forms a depression 216, which is defined by the surrounding portions of the ILD isolation stack 210 and the top of the polysilicon contact plug 202. This etching process can be done by any etching or material removal process that is selective over the material that forms the top of the ILD isolation stack 210 and the polysilicon layer 214.

The process would next form the contact holes 204 for the metal contact plugs, as shown in FIG. 2C. A mask layer 218 is formed and patterned over the top of the ILD isolation stack 210. In FIG. 2C, a mask layer 218 is formed overlying the structure to define areas for removal of the ILD isolation stack 210. As one example, the mask layer 218 is a patterned photoresist layer as is commonly used in semiconductor fabrication. The exposed areas of the ILD isolation stack are then removed in FIG. 2C such as by dry etching, wet etching, anisotropic etching, or other removal process. This exposes portions of the silicon active area 208 at one or more regions forming contact holes. It is noted that the contact holes for the polysilicon contact plugs 202 and the metal contact plugs 204 may be formed either together or separately using one or more separate mask and etch steps.

After the layer of photo resist 218 has been patterned and the exposed ILD isolation stack is etched to expose the silicon active area 208, the layer of photo resist 218 is then stripped off, as shown in FIG. 2D, to reveal the formed contact holes for the metal contact plugs 204 and the polysilicon top depressions 216 of the polysilicon contact plugs 202.

As detailed in FIG. 2E layer of contact liner material 220 is then deposited over the memory array 200 filling the top depressions 216 of the polysilicon contact plugs 202 and the metal contact holes 204 with contact liner material 220. The contact liner material 220 is then mechanically polished utilizing chemical mechanical polishing (CMP) or etched level with the top of the ILD isolation stack layer 210, leaving contact material 220 in the top depression 216 of the polysilicon contact plugs 202 and in the metal contact plug hole forming a metal contact plug 204. The contact material 220 in the top depression 216 of the polysilicon contact plugs 202 forms a barrier layer 222 of at least the thickness of the depression 216 for the polysilicon contact plugs 202, as shown in FIG. 2F. As stated above contact liner material is defined as any material providing barrier and/or adhesion characteristics between the silicon and the subsequent metal layer. These contact liner materials can include, but are not limited to, tungsten, titanium, and titanium nitride.

A metal layer, which can be of, but is not limited to, copper, tungsten, or aluminum, is then deposited over the top of the ILD isolation stack 210, where it is patterned and etched, as detailed in FIG. 2F, to form metal interconnect lines 206. The formed metal interconnect lines 206 are in contact with the metal contact plugs 204 and the contact liner material of the barrier layer 222 of the polysilicon contact plugs 202. The thicker barrier/liner layer 222 of polysilicon contact plugs 202 thus formed in embodiments of the present invention provide an improved barrier between polysilicon and metal to diffusion, making it less subject to faults with improved thickness and edge coverage of the underlying polysilicon contact plugs 202. The thicker barrier/liner layer 222 of polysilicon contact plugs 202 also allow for concurrent formation of metal contact plugs 204.

FIG. 3 illustrates a functional block diagram of a memory device 300 that incorporates the improved polysilicon barrier layers, metal contact plugs, and methods of the present invention. The memory device 300 is coupled to a processor 310. The processor 310 may be a microprocessor or some other type of controlling circuitry. The memory device 300 and the processor 310 form part of an electronic system 320. The memory device 300 has been simplified to focus on features of the memory that are helpful in understanding the present invention.

The memory device includes an array of memory cells 330. In one embodiment, the memory cells are floating gate memory cells of a Flash memory device and the memory array 330 is arranged in banks of rows and columns. The control gates of each row of memory cells are coupled with a wordline while the drain connections of the memory cells are coupled to bitlines and the source connections are coupled to source lines. As is well known in the art, the connection of the cells to the bitlines depends on whether the array is a NAND architecture or a NOR architecture. The contacts to one or more of the wordlines, bitlines, and/or source lines of the memory array are made utilizing polysilicon contact plugs, polysilicon barrier layers and metal contact plugs in accordance with embodiments of the present invention.

An address buffer circuit 340 is provided to latch address signals provided on address/data bus 362. Address signals are received and decoded by a row decoder 344 and a column decoder 346 to access the memory array 330. It will be appreciated by those skilled in the art, with the benefit of the present description, that the size of address input on the address/data bus 362 depends on the density and architecture of the memory array 330. That is, the size of the input address increases with both increased memory cell counts and increased bank and block counts. It is noted that other address input manners, such as through a separate address bus, are also known and will be understood by those skilled in the art with the benefit of the present description.

The memory device 300 reads data in the memory array 330 by sensing voltage or current changes in the memory array columns using sense/buffer circuitry 350. The sense/buffer circuitry, in one embodiment, is coupled to read and latch a row of data from the memory array 330. Data input and output buffer circuitry 360 is included for bi-directional data communication over a plurality of data connections in the address/data bus 362 with the processor/controller 310. Write circuitry 355 is provided to write data to the memory array.

Control circuitry 370 decodes signals provided on control connections 372 from the processor 310. These signals are used to control the operations on the memory array 330, including data read, data write, and erase operations. The control circuitry 370 may be a state machine, a sequencer, or some other type of controller.

The memory device illustrated in FIG. 3 has been simplified to facilitate a basic understanding of the features of the memory. A more detailed understanding of internal circuitry and functions of memories are known to those skilled in the art.

It is noted that the polysilicon contact plugs and barrier layers of memory embodiments of the present invention can apply to other volatile and non-volatile memory types including, but not limited to, SDRAM, DDR, dynamic RAM, static RAM, ROM, EEPROM, NOR architecture Flash memory, NAND architecture Flash memory, Ferroelectric Random Access Memory (FeRAM), Nitride Read Only Memory (NROM), and Magnetoresistive Random Access Memory (MRAM) and should be apparent to those skilled in the art with the benefit of the present invention.

As stated above, the memory device 300 has been simplified to facilitate a basic understanding of the features of the memory device. A more detailed understanding of flash memories and memories in general is known to those skilled in the art. As is well known, such memory devices 300 may be fabricated as integrated circuits on a semiconductor substrate.

It is also noted that other polysilicon diffusion barriers/contact liners and metal contact plugs in integrated circuit or memory devices in accordance with embodiments of the present invention are possible and should be apparent to those skilled in the art with benefit of the present disclosure.

### CONCLUSION

Methods and apparatus have been described to facilitate forming of polysilicon contact plugs with an improved diffusion barrier that can be formed in conjunction with other process steps. Embodiments of the present invention are formed by recessing the polysilicon plug below the surface of the insulation layer, allowing the depression formed at the interface of the insulating layer and the top of the polysilicon plug to be filled with a diffusion barrier/liner layer. This also allows the etching of the polysilicon contact plug and deposition of the barrier layer to occur concurrent with formation of metal contact plugs and before deposition and etching of the metal interconnection layer. In one embodiment of the present invention, both metal contact plugs and polysilicon contact plugs are deposited with liner material in a single process step. In another embodiment of the present invention the peripheral tungsten metal contact plugs are formed and the polysilicon contact plugs of a memory array are deposited with liner material and removed in a series of concurrent process steps and a layer of aluminum is deposited and removed to form metal interconnect lines in contact with the peripheral tungsten metal and polysilicon contact plugs.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

1. A portion of an integrated circuit, comprising:
a polysilicon contact plug in contact with a first active area of the integrated circuit and a liner material overlying the polysilicon plug; and
a metal contact in contact with a second active area of the integrated circuit; and
wherein the metal contact and the liner material of the polysilicon contact plug are formed concurrently.

2. The portion of an integrated circuit of claim 1, wherein the liner material and the metal contact each further comprise a first metal layer overlying a conductive barrier layer.

3. The portion of an integrated circuit of claim 1, further comprising:
a metal interconnect line in contact with a surface of the polysilicon contact plug and the metal contact.

4. A method of forming a portion of an integrated circuit, comprising:
forming a dielectric layer overlying a silicon active area of the integrated circuit;
forming a first contact hole in the dielectric layer exposing a first portion of the silicon active area;
forming a polysilicon layer overlying the dielectric layer and contacting the first portion of the silicon active area;
removing a portion of the polysilicon layer to leave a polysilicon plug in the first contact hole, wherein a surface of the polysilicon plug is recessed below a surface of the dielectric layer;
forming a second contact hole in the dielectric layer exposing a second portion of the silicon active area;
forming a conductive layer overlying the dielectric layer and contacting the surface of the polysilicon plug and the second portion of the silicon active area; and
removing a portion of the conductive layer to leave portions of the conductive layer in the second contact hole and in the first contact hole between the surface of the dielectric layer and the surface of the polysilicon plug.

5. The method of claim 4, further comprising:
forming a metal layer overlying the dielectric layer and in contact with the portions of the conductive layer in the second contact hole and the first contact hole; and
patterning the metal layer to define an interconnect line coupling the portion of the conductive layer in the second contact hole to the portion of the conductive layer in the first contact hole.

7. The method of claim 4, wherein forming the conductive layer further comprises:
forming a conductive barrier layer overlying the dielectric layer and contacting the surface of the polysilicon plug and the second portion of the silicon active area; and
forming a first metal layer overlying the conductive barrier layer.

8. The method of claim 7, further comprising:
forming a second metal layer overlying the dielectric layer and in contact with portions of the first metal layer in the second contact hole and the first contact hole; and
patterning the second metal layer to define an interconnect line coupling the portion of the first metal layer in the second contact hole to the portion of the first metal layer in the first contact hole.

9. A method of forming polysilicon and metal contact plugs, comprising:
forming an insulation layer overlying an active area of an integrated circuit;
forming one or more first and second contact holes in the insulation layer;
forming a polysilicon layer over the insulation layer in contact with the active area through the one or more first contact holes;
removing a portion of the polysilicon layer to form one or more polysilicon contact plugs in the one or more contact holes, wherein a top surface of each of the one or more polysilicon contact plugs are formed below a top surface of the insulation layer;
forming a contact liner material layer over the insulation layer in contact with the top surface of each of the one or more polysilicon contact plugs and second contact holes; and
removing a portion of the contact liner material layer to form a diffusion barrier over each polysilicon contact plug in the one or more contact holes and one or more metal contact plugs in the one or more second contact holes.

10. The method of claim 9, further comprising:
forming a metal layer in contact with the diffusion barrier of each contact plug.

11. The method of claim 10, wherein forming a metal layer in contact with the diffusion barrier of each contact plug further comprises masking and etching the metal layer to form one or more metal interconnect lines.

12. The method of claim 10, wherein forming a metal layer in contact with the diffusion barrier of each contact plug further comprises forming a metal layer of one of aluminum, tungsten, and copper.

13. The method of claim 9, wherein forming a contact liner material layer over the insulation layer further comprises forming a contact liner material layer of one of tungsten, titanium, and titanium nitride.

14. The method of claim 9, wherein removing a portion of the contact liner material layer to form a diffusion barrier over each polysilicon contact plug in the one or more contact holes further comprises removing a portion of the contact liner material layer to form diffusion barriers for the one or more polysilicon contact plugs where a top surface of each diffusion barrier is substantially level with the top surface of the insulation layer.

15. A method of fabricating a memory array, comprising:
forming an interlayer dielectric (ILD) isolation stack overlying an active area of memory array;
forming one or more first and second contact holes in the ILD isolation stack;
forming a polysilicon layer over the ILD isolation stack in contact with the silicon active area through the one or more first contact holes;
removing a portion of the polysilicon layer to form one or more polysilicon contact plugs in the one or more first contact holes, wherein a top surface of each of the one or more polysilicon contact plugs are formed below a top surface of the ILD isolation stack;
forming a contact liner material layer over the ILD isolation stack in contact with the top surface of each of the one or more polysilicon contact plugs and the active area through the one or more second contact holes; and
removing a portion of the contact liner material layer to form a diffusion barrier over each polysilicon contact plug in the one or more contact holes and form one or more metal contact plugs in the one or more second contact holes.

16. The method of claim 15, wherein the memory array is a non-volatile memory array.

17. The method of claim 15, further comprising:
forming a metal layer in contact with one or more metal and/or polysilicon contact plugs.

18. The method of claim 17, wherein forming a metal layer in contact one or more metal and/or polysilicon contact plugs further comprises masking and etching the metal layer to form one or more metal interconnect lines.

19. The method of claim 17, wherein forming a metal layer in contact with one or more metal and/or polysilicon contact plugs further comprises forming a metal layer of one of aluminum, tungsten, and copper.

20. The method of claim 15, wherein forming one or more metal contact plugs in the one or more second contact holes further comprises filling the one or more second contact holes with liner material to form one or more metal contact plugs concurrently with the forming the diffusion barriers of the one or more polysilicon contact plugs.

21. The method of claim 15, wherein forming a contact liner material layer over the ILD isolation stack in contact with the top surface of each of the one or more polysilicon contact plugs and the active area through the one or more second contact holes further comprises forming a contact liner material layer of one of tungsten, titanium, and titanium nitride.

22. The method of claim 15, wherein removing a portion of the contact liner material layer to form a diffusion barrier over each polysilicon contact plug in the one or more contact holes and form one or more metal contact plugs in the one or more second contact holes further comprises removing a portion of the contact liner material layer to form diffusion barriers for the polysilicon contact plugs where a top surface of each diffusion barrier is substantially level with the top surface of the ILD isolation stack.

23. A method of forming an integrated circuit, comprising:
forming the active area of a memory array containing a plurality of floating gate memory cells;
forming an insulation layer overlying the active area;
forming one or more first and second contact holes in the insulation layer;
forming a polysilicon layer over the insulation layer in contact with the active area through the one or more first contact holes;
removing a portion of the polysilicon layer to form one or more polysilicon contact plugs in the one or more first contact holes, wherein a top surface of each of the one or more polysilicon contact plugs are formed below a top surface of the insulation layer;
forming one or more metal contact plugs in the one or more second contact holes;
forming a contact liner material layer over the insulation layer in contact with the top surface of each of the one or more polysilicon contact plugs and one or more metal contact plugs; and
removing a portion of the contact liner material layer to form a diffusion barrier over each polysilicon contact plug and metal contact plug.

24. The method of claim 23, wherein the integrated circuit is a memory device.

25. The method of claim 24, wherein the memory device is a non-volatile memory device.

26. The method of claim 23, wherein further comprising:
forming a metal layer in contact with the diffusion barrier of one or more polysilicon and/or metal contact plugs.

27. The method of claim 26, wherein forming a metal layer in contact with the diffusion barrier of one or more polysilicon and/or metal contact plugs further comprises masking and etching the metal layer to form one or more metal interconnect lines.

28. The method of claim 26, wherein forming a metal layer in contact with the diffusion barrier of one or more polysilicon and/or metal contact plugs further comprises forming a metal layer of one of aluminum, tungsten, and copper.

29. The method of claim 23, wherein forming one or more metal contact plugs in the one or more second contact holes further comprises filling the one or more second contact holes with liner material to form one or more metal contact plugs concurrently with the forming the diffusion barriers of the one or more polysilicon contact plugs.

30. The method of claim 23, wherein forming a contact liner material layer over the insulation layer in contact with the top surface of each of the one or more polysilicon contact plugs and one or more metal contact plugs further comprises forming a contact liner material layer of one of tungsten, titanium, and titanium nitride.

31. The method of claim 23, wherein removing a portion of the contact liner material layer to form a diffusion barrier over each polysilicon contact plug in the one or more first contact holes and one or more metal contact plugs further comprises removing a portion of the contact liner material layer to form diffusion barriers for the one or more polysilicon contact plugs where a top surface of each diffusion barrier is substantially level with the top surface of the insulation layer.

32. The method of claim 23, wherein forming one or more first and second contact holes in the insulation layer further comprises:
forming a mask layer overlying the insulation layer;
patterning the mask layer to expose a portion of the insulation layer;
removing a portion of the exposed portion of the insulation layer material to expose the active area; and
removing the mask layer.

33. The method of claim 32, wherein forming a mask layer further comprises forming a mask layer with a photoresist.

34. The method of claim 32, wherein removing the mask layer further comprises stripping the mask layer.

35. The method of claim 32, wherein removing a portion of the exposed portion of the insulation layer material to expose the silicon active area further comprises anisotropically etching the exposed portion of the insulation layer material.

36. A method of forming a Flash memory device, comprising:
forming the silicon active area of a memory array containing a plurality of floating gate memory cells;
forming an interlayer dielectric (ILD) isolation stack overlying the silicon active area;
forming one or more first and second contact holes in the ILD isolation stack;
forming a polysilicon layer over the ILD isolation stack in contact with the silicon active area through the one or more first contact holes;
removing a portion of the polysilicon layer to form one or more polysilicon contact plugs in the one or more first contact holes, wherein a top surface of each of the one or more polysilicon contact plugs are formed below a top surface of the ILD isolation stack;
forming one or more metal contact plugs in the one or more second contact holes;
forming a contact liner material layer over the ILD isolation stack in contact with the top surface of each of the one or more polysilicon and metal contact plugs; and
removing a portion of the contact liner material layer to form a diffusion barrier over the polysilicon and metal contact plugs.

37. The method of claim 36, wherein the Flash memory device is one of a NAND Flash memory device and a NOR Flash memory device.

38. The method of claim 36, wherein further comprising:
forming a metal layer in contact with the diffusion barrier of one or more polysilicon and/or metal contact plugs.

39. The method of claim 38, wherein forming a metal layer in contact with the diffusion barrier of one or more polysilicon and/or metal contact plugs further comprises masking and etching the metal layer to form one or more metal interconnect lines.

40. The method of claim 38, wherein forming a metal layer in contact with the diffusion barrier of one or more polysilicon and/or metal contact plugs further comprises forming a metal layer of one of aluminum, tungsten, and copper.

41. The method of claim 36, wherein forming one or more metal contact plugs further comprises filling the one or more second contact holes with liner material to form one or more metal contact plugs concurrently with the forming the diffusion barriers of the one or more polysilicon contact plugs.

42. The method of claim 36, wherein forming a contact liner material layer over the ILD isolation stack in contact with the top surface of each of the one or more polysilicon and metal contact plugs further comprises forming a contact liner material layer of one of tungsten, titanium, and titanium nitride.

43. The method of claim 36, wherein removing a portion of the contact liner material layer to form a diffusion barrier over the polysilicon and metal contact plugs further comprises removing a portion of the contact liner material layer to form diffusion barriers for the one or more polysilicon contact plugs where a top surface of each diffusion barrier is substantially level with the top surface of the ILD isolation stack.

44. A memory array, comprising:
an array of memory cells;
an interlayer dielectric (ILD) isolation layer placed over the array, wherein the ILD isolation layer has one or more first and second contact holes;
one or more polysilicon contact plugs wherein the polysilicon contact plugs are formed within the one or more first contact holes of the ILD isolation layer, where a top surface of each of the one or more polysilicon contact plugs is positioned below a top surface of the ILD isolation layer, defining one or more depressions;
one or more barrier layers of contact liner material placed in each of the one or more depressions;
one or more metal contact plugs, wherein the metal contact plugs are formed in the one or more second contact holes; and
at least one metal interconnect line in contact with the one or more barrier layers and/or metal contact plugs.

45. The memory array of claim 44, wherein the memory array is a non-volatile memory array.

46. The memory array of claim 45, wherein the non-volatile memory array is one of a NOR architecture Flash memory array, a NAND architecture Flash memory array, a Ferroelectric Random Access Memory (FeRAM) memory array, a Nitride Read Only Memory (NROM) array, and a Magnetoresistive Random Access Memory (MRAM) memory array.

47. The memory array of claim 44, wherein the contact liner material is one of tungsten, titanium, and titanium nitride.

48. The memory array of claim 44, wherein the at least one metal interconnect line is one of a tungsten interconnect line, an aluminum interconnect line, and a copper interconnect line.

49. The memory array of claim 44, wherein the metal contact plugs are formed of contact liner material concurrently with the barrier layers.

50. An integrated circuit, comprising:
a silicon active area;
an insulation layer placed over the active area, wherein the insulation layer has one or more first and second contact holes;
one or more polysilicon contact plugs placed within the one or more first contact holes of the insulation layer, wherein a top surface of each of the one or more polysilicon contact plugs is positioned below a top surface of the insulation layer, defining one or more depressions;
one or more barrier layers of contact liner material, wherein the barrier layers are formed in each of the one or more depressions;
one or more metal contact plugs, wherein the metal contact plugs are formed in the one or more second contact holes; and
at least one metal interconnect line in contact with the one or more barrier layers and/or metal contact plugs.

51. The integrated circuit of claim 50, wherein the integrated circuit is a memory device.

52. The integrated circuit of claim 50, wherein the contact liner material is one of tungsten, titanium, and titanium nitride.

53. The integrated circuit of claim 50, wherein the at least one metal interconnect line is one of a tungsten interconnect line, an aluminum interconnect line, and a copper interconnect line.

54. The integrated circuit of claim 50, wherein the metal contact plugs are formed of contact liner material concurrently with the barrier layers.

55. A memory device, comprising:
an array of memory cells;
an insulation layer placed over the array, wherein the insulation layer has one or more first and second contact holes;
one or more polysilicon contact plugs placed within the one or more first contact holes of the insulation layer, wherein a top surface of each of the one or more polysilicon contact plugs is positioned below a top surface of the insulation layer, defining one or more depressions;
one or more barrier layers of contact liner material, wherein the barrier layers are formed in each of the one or more depressions;
one or more metal contact plugs, wherein the metal contact plugs are formed in the one or more second contact holes; and
at least one metal interconnect line in contact with the one or more barrier layers and/or metal contact plugs.

56. The memory device of claim 55, wherein the memory device is a non-volatile memory device.

57. The memory device of claim 56, wherein the non-volatile memory device is one of a NOR architecture Flash memory device, a NAND architecture Flash memory device, a Ferroelectric Random Access Memory (FeRAM) memory device, a Nitride Read Only Memory (NROM) device, and a Magnetoresistive Random Access Memory (MRAM) memory device.

58. The memory device of claim 55, wherein the contact liner is one of tungsten, titanium, and titanium nitride.

59. The memory device of claim 55, wherein the at least one metal interconnect line is one of a tungsten interconnect line, an aluminum interconnect line and a copper interconnect line.

60. The memory device of claim 55, wherein the metal contact plugs are formed of contact liner material concurrently with the barrier layers.

61. A system, comprising:
a processor coupled to a memory device, wherein the memory device comprises, an array of memory cells;
an interlayer dielectric (ILD) isolation layer placed over the array, wherein the ILD isolation layer has one or more first and second contact holes;
one or more polysilicon contact plugs placed within the one or more first contact holes of the ILD isolation layer, wherein a top surface of each of the one or more polysilicon contact plugs is positioned below a top surface of the ILD isolation layer, defining one or more depressions;
one or more barrier layers of contact liner material, wherein the barrier layers are formed in each of the one or more depressions;
one or more metal contact plugs, wherein the metal contact plugs are formed of contact liner material in the one or more second contact holes concurrently with the one or more barrier layers; and
at least one metal interconnect line in contact with the one or more barrier layers and/or metal contact plugs.

62. The system of claim 61, wherein the memory device is a non-volatile memory device.

63. The system of claim 62, wherein the non-volatile memory device is one of a NOR architecture Flash memory device, a NAND architecture Flash memory device, a Ferroelectric Random Access Memory (FeRAM) memory device, a Nitride Read Only Memory (NROM) device, and a Magnetoresistive Random Access Memory (MRAM) memory device.

64. The system of claim 61, wherein the processor is a memory controller.

65. A memory device, comprising:
an array of memory cells;
an insulation layer placed over the array, wherein the insulation layer has one or more first contact holes;
one or more polysilicon contact plugs placed within the one or more first contact holes of the insulation layer, having a means for defining one or more depressions between a top surface of each of the one or more polysilicon contact plugs and a top surface of the ILD isolation layer;
a means for forming one or more barrier layers of contact liner material in each of the one or more depressions;
a means for forming one or more metal contact plugs, wherein the metal contact plugs are formed in the one or more second contact holes; and
a means for forming at least one metal interconnect line in contact with the one or more barrier layers and/or metal contact plugs.

66. The memory device of claim 65, wherein the memory device is a non-volatile memory device.

67. The memory device of claim 66, wherein the non-volatile memory device is one of a NOR architecture Flash memory device, and a NAND architecture Flash memory device.

68. An integrated circuit, comprising:
a silicon active area;
an insulation layer placed over the active area, wherein the insulation layer has one or more contact holes;
one or more polysilicon contact plugs placed within the one or more contact holes of the insulation layer, wherein a top surface of each of the one or more polysilicon contact plugs is positioned below a top surface of the insulation layer, defining one or more depressions;
one or more barrier layers of contact liner material, wherein the barrier layers are formed in each of the one or more depressions; and
at least one metal interconnect line in contact with the one or more barrier layers and/or metal contact plugs.

69. The integrated circuit of claim 68, wherein the integrated circuit is a memory device.

70. The integrated circuit of claim 68, wherein the contact liner material is one of tungsten, titanium, and titanium nitride.

71. The integrated circuit of claim 68, wherein the at least one metal interconnect line is one of a tungsten interconnect line, an aluminum interconnect line, and a copper interconnect line.

72. The integrated circuit of claim 68, wherein one or more metal contact plugs are formed in the insulation layer in one or more second contact holes, wherein the metal contact plugs are formed concurrently with the one or more polysilicon contact plugs and barrier layers.

73. A method of forming a portion of an integrated circuit, comprising:
forming a dielectric layer overlying a silicon active area of the integrated circuit;
forming a contact hole in the dielectric layer exposing a portion of the silicon active area;
forming a polysilicon layer overlying the dielectric layer and contacting the portion of the silicon active area;
removing a portion of the polysilicon layer to leave a polysilicon plug in the contact hole, wherein a top surface of the polysilicon plug is recessed below a surface of the dielectric layer; and
forming a layer of barrier material overlying the dielectric layer and contacting the surface of the polysilicon plug, filling the formed recess between the top surface of the polysilicon plug and the surface of the dielectric layer; and
removing a portion of the barrier layer to leave portions of the barrier layer in the formed recess of the contact hole between the surface of the dielectric layer and the top surface of the polysilicon plug.

74. The method of claim 73, further comprising:
forming a metal layer overlying the dielectric layer and in contact with the portions of the barrier layer in the contact hole; and
patterning the metal layer to define an interconnect line.

75. The method of claim 73, wherein forming a layer of barrier material overlying the dielectric layer and contacting the surface of the polysilicon plug further comprises:
forming a layer of barrier material of one or more differing material layers overlying the dielectric layer and contacting the surface of the polysilicon plug.

76. A method of forming polysilicon contact plugs, comprising:
forming an insulation layer overlying an active area of an integrated circuit;
forming one or more contact holes in the insulation layer;
forming a polysilicon layer over the insulation layer in contact with the active area through the one or more contact holes;
removing a portion of the polysilicon layer to form one or more polysilicon contact plugs in the one or more contact holes, wherein a top surface of each of the one or more polysilicon contact plugs are formed below a top surface of the insulation layer; and
forming a contact liner material layer over the insulation layer in contact with the top surface of each of the one or more polysilicon contact plugs to form a diffusion barrier over each polysilicon contact plug in the one or more contact holes.

77. The method of claim 76, further comprising:
forming a metal layer in contact with the diffusion barrier of each contact plug.

78. The method of claim 77, wherein forming a metal layer in contact with the diffusion barrier of each contact plug further comprises masking and removing portions of the metal layer and underlying contact liner material layer to form one or more metal interconnect lines.

79. The method of claim 77, wherein forming a metal layer in contact with the diffusion barrier of each contact plug further comprises forming a metal layer of one of aluminum, tungsten, and copper.

80. The method of claim 76, wherein forming a contact liner material layer over the insulation layer further comprises forming a contact liner material layer of one or more of tungsten, titanium, and titanium nitride.
